(19) United States
(12) Patent Application Publication
(10) Pub. No.: US 2011/0159774 A1
(43) Pub. Date: Jun. 30, 2011

(54) SHADOW MASK AND METHOD OF MAKING THE SAME

(76) Inventors: Yi-Hwa Song, Hsin-Chu (TW); Shih-Feng Hsu, Hsin-Chu (TW)

(21) Appl. No.: 12/957,422

(22) Filed: Dec. 1, 2010

(30) Foreign Application Priority Data
Dec. 29, 2009 (TW) 098145547

(51) Int. Cl. H01J 9/00; B23P 11/00

(52) U.S. Cl. 445/60; 29/434

(57) ABSTRACT

A shadow mask includes a frame, at least a support structure and at least a mask. The frame substantially defines a central opening region. The support structure is substantially disposed in the central opening region, and the support structure is connected to the frame in a movable manner. The mask is substantially disposed in the central opening region, and supported by the support structure.

### BACKGROUND OF THE INVENTION

1. Field of the Invention

The present invention relates to a shadow mask and a method of making the same, and more particularly, to a shadow mask having a support structure connected to a frame in a movable manner, and a method of making the same.

2. Description of the Prior Art

Among various types of flat display devices in present days, electro luminescent (EL) display device, e.g. organic light-emitting diode (OLED) display device has become the most well expected flat display products due to its advantages such as high contrast ratio and self luminance. Currently, the organic light-emitting layer of the OLED display devices is primarily formed by an evaporation process, and the pattern of the organic light-emitting layer is defined by a shadow mask in the evaporation process. As the scale of the OLED display panel is getting larger, the size of the shadow mask for the evaporation process is also increased. Large-sized shadow mask, however, possesses the issue of bending due to its additional weight. Furthermore, the support structure of conventional shadow mask is disposed immovably, and thus the shadow mask can only be used in the evaporation process of a particular type of OLED display panel, which lack the flexibility in applications.

Therefore, to improve the structure strength of the shadow mask without increasing the overall weight significantly has become one of the key issues to be considered in manufacturing large-scale OLED display devices.

### SUMMARY OF THE INVENTION

It is therefore one of the objectives of the present invention to provide a shadow mask and a method of making the same, so as to achieve weight reduction of large-sized shadow mask and to expand the applicability of shadow mask.

A shadow mask is provided in accordance with a preferred embodiment of the present invention. The shadow mask includes a frame, at least a support structure and at least a mask. The frame substantially defines a central opening region. The support structure is substantially disposed in the central opening region, and the support structure is connected to the frame in a movable manner. The mask is substantially disposed in the central opening region, and the mask is supported by the support structure.

A method of fabricating a shadow mask in accordance with another preferred embodiment of the present invention includes the following steps. A frame is provided and the frame substantially defines a central opening region. At least a support structure is connected to at least a first connecting position of the frame in a movable manner, and the support structure is disposed in the central opening region. At least a mask is substantially disposed in the central opening region, and the mask is supported by the support structure.

The shadow mask in accordance with the present invention includes a support structure connected to the frame in a movable manner, and the support structure can be made of high strength and light weight materials so that the shadow mask can achieve higher structure strength while still exhibiting light weight characteristic. Also, the support structure disposed in movable manner further increases the applicability of the shadow mask.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 are schematic diagrams illustrating a method of fabricating a shadow mask in accordance with a preferred embodiment of the present invention.

FIG. 8 and FIG. 9 are schematic diagrams illustrating a shadow mask in accordance with another embodiment of the present invention.

### DETAILED DESCRIPTION

To provide a better understanding of the presented invention, a preferred embodiment will be made in details. The preferred embodiment of the present invention is illustrated in the accompanying drawings with numbered elements. In addition, the accompanying drawings of the present invention are for the purpose of illustration only, and the scales of the drawings may not be exact.

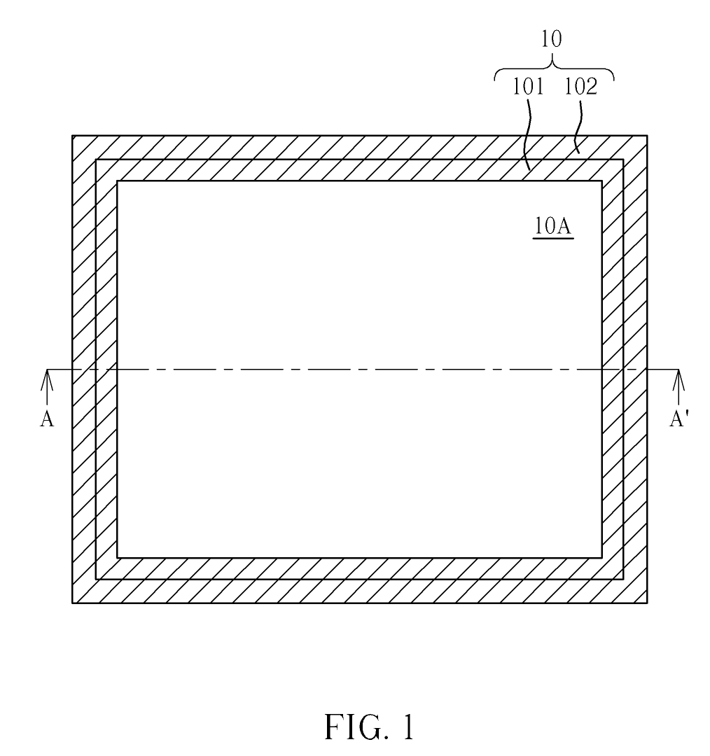

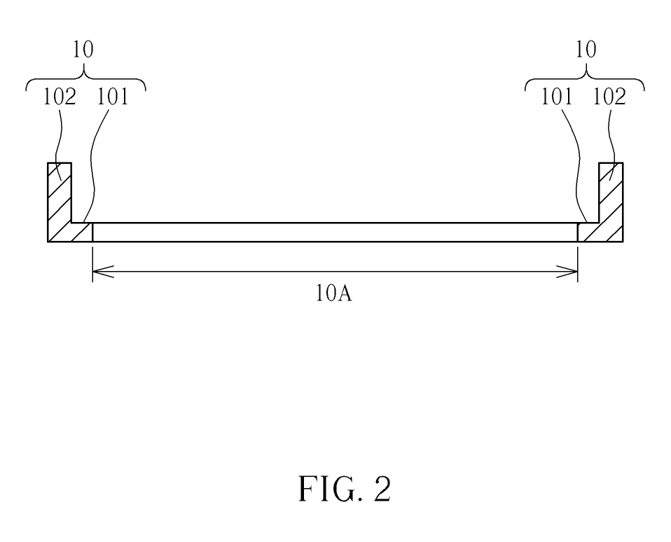

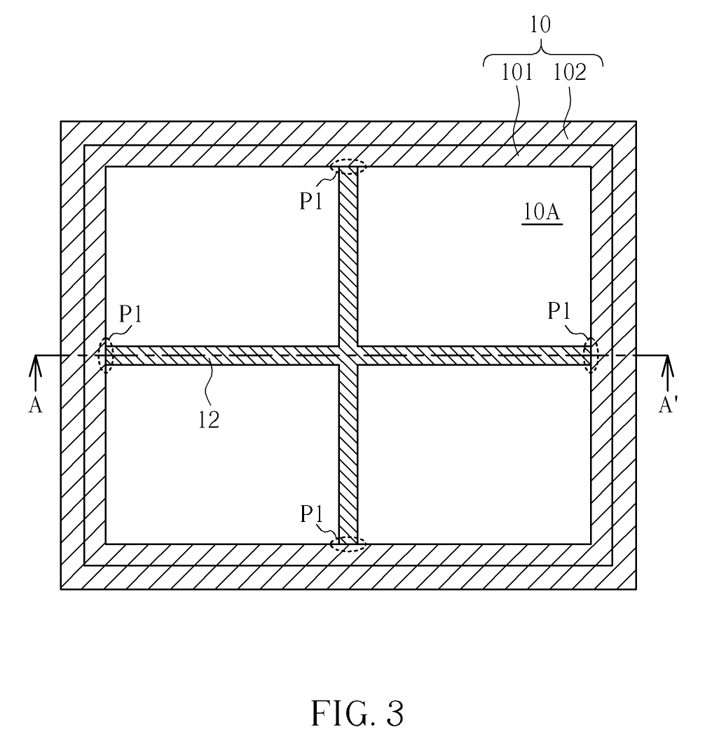

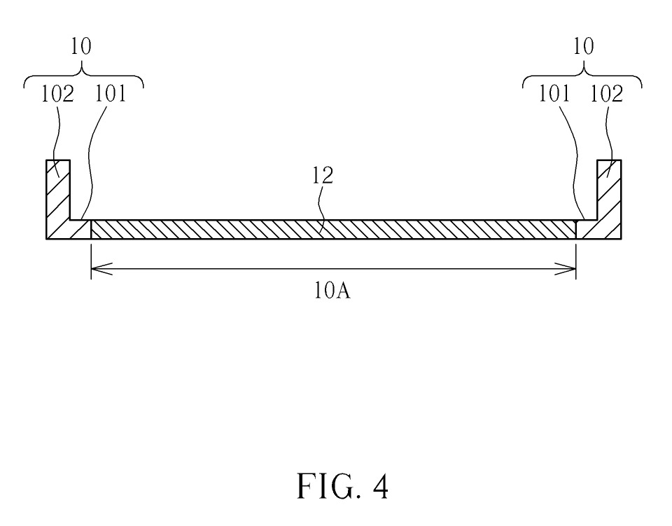

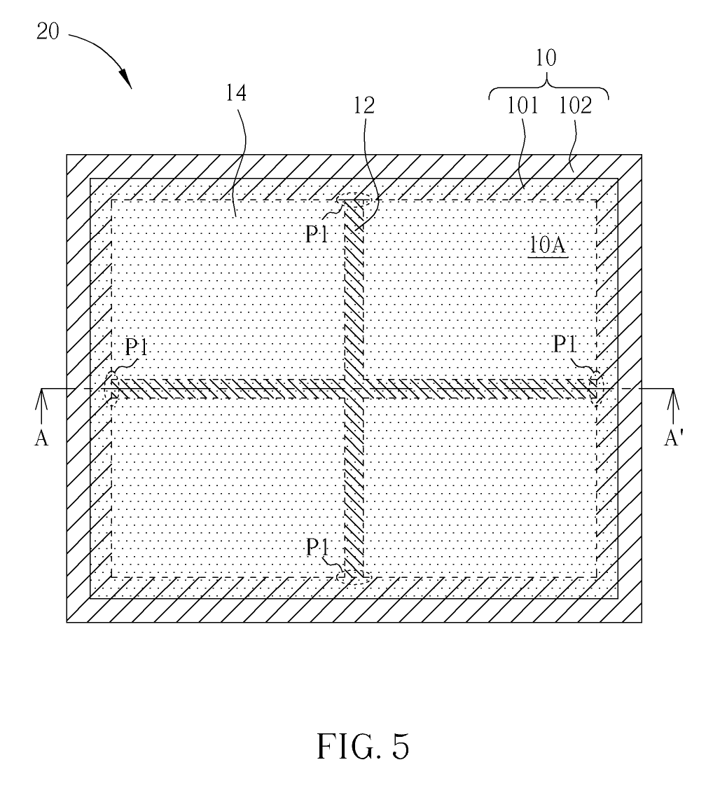

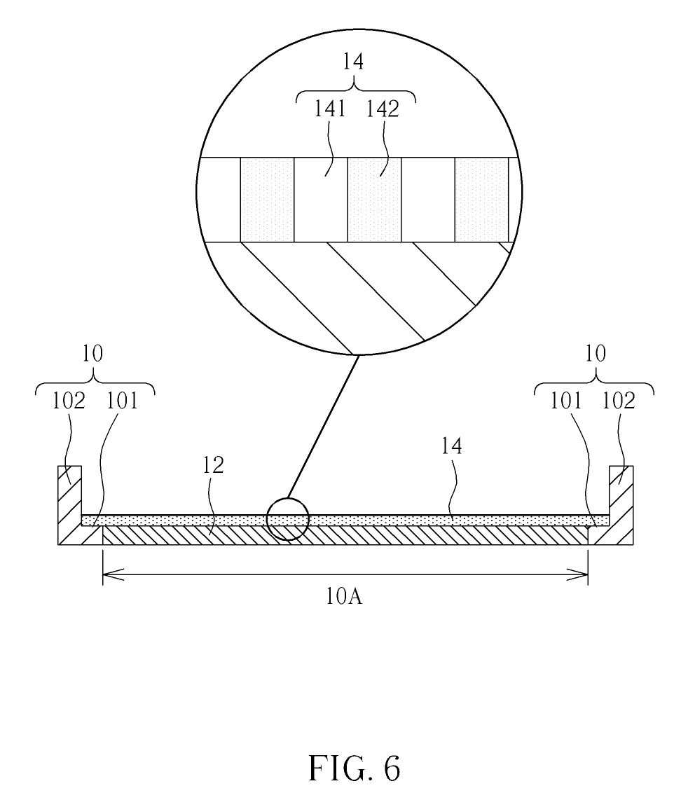

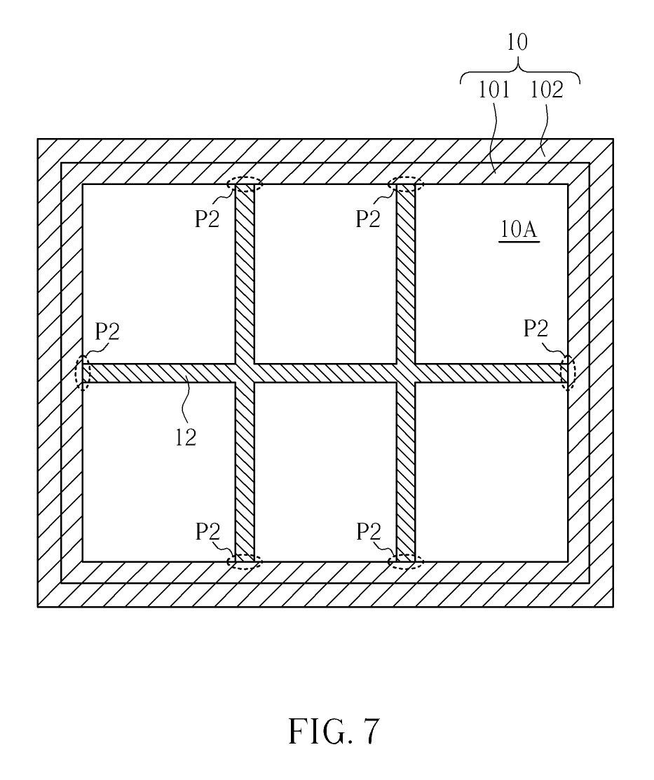

Referring to FIG. 1 to FIG. 7, FIG. 1 to FIG. 7 are schematic diagrams illustrating a method of fabricating a shadow mask in accordance with a preferred embodiment of the present invention. FIG. 1, FIG. 3, FIG. 5 and FIG. 7 are schematic top view diagrams, and FIG. 2, FIG. 4 and FIG. 6 are schematic cross-sectional diagrams along line A-A′ of FIG. 1, FIG. 3 and FIG. 5 respectively. As illustrated in FIG. 1 and FIG. 2, a frame 10 is provided. The frame 10 in accordance with the present embodiment includes a hollow frame structure, e.g. a rectangular hollow frame, and the frame 10 substantially defines a central opening region 10A. The frame 10 may be a monolithically and integrally formed structure, or an assembly of a plurality of parts. The hollow frame structure in accordance with the present embodiment includes a first part 101 and a second part 102. The first part 101 and the second part 102 are connected with each other; the first part 101 is disposed near the central opening region 10A, whereas the second part 102 is disposed away from the central opening region 10A. The thickness of the first part 101 is thinner than the thickness of the second part 102 so that the hollow frame structure has an L-shaped cross-section. The frame 10 in accordance with the present embodiment may be made of any appropriate materials, and preferably be made of materials with high strengths or low thermal expansion coefficients. For example, the frame 10 may be made of any kinds of metal or metal alloy, e.g. Invar or SUS304 stainless steel, but is not limited thereto.

As illustrated in FIG. 3 and FIG. 4, at least a support structure 12 is subsequently connected to first connecting positions P1 of the frame 10 in a movable manner, and the support structure 12 is disposed in the central opening region 10A. The present embodiment utilizes two support structures 12 and assembles the two support structures 12 into a cross-like structure. Each of the ends of the cross-like structure is respectively connected to one first connecting position P1 of the frame 10 in a movable manner. The first connecting positions P1 are located on an inner surface of the first part 101 of the frame 10. In addition, the support structure 12 in accordance with the present embodiment is preferably made of light weight and high strength materials, e.g. Invar or SUS304 stainless steel, so that the overall weight of the shadow mask can be reduced, but is not limited thereto. The support structure 12 and the frame 10 may be made of the same material or different materials. Furthermore, as the scale of the frame 10 or the strength requirement of the frame 10 varies, the number and shape of support structure 12, and the positions of the first connecting positions P1 may be adjusted accordingly. In the present embodiment, connecting the support structure 12 and the first connecting positions P1 of the frame 10 in a movable manner represents that the support structure 12 may be disconnected (detached) from the frame 10 through reworks or other methods wherever necessary. Also, the detached support structure 12 can be reconnected to other positions of the frame 10. For example, the support structure 12 may be reconnected with the frame 10 by laser welding. When the design of the shadow mask is modified, the support structure 12 may be removed from the frame 10 by e.g. melting or cutting, while the detached support structure 12 may be then reconnected to other positions of the frame 10. The moveable connection between the support structure 12 and the frame 10 is not limited to be implemented by laser welding, and may be implemented by other moveable connection methods. For instance, the support structure 12 and the frame 10 may be movably connected by fixing parts (e.g. screws), by adhesive or by embedding the support structure 12 into the frame 10. Based on different connecting method, the support structure 12 may be detached from the frame 10 by any appropriate methods, and the connecting position between the support structure 12 and the frame 10 may be adjusted accordingly.

As illustrated in FIG. 5 and FIG. 6, at least a mask 14 is then disposed on the support structure 12 in the central opening region 10A so that the mask 14 is supported by both the support structure 12 and the frame 10, forming the shadow mask 20 of the present embodiment. To be exact, the mask 14 is disposed on the support structure 12 and on the first part 101 of the hollow frame structure, and the mask 14 is lodged in the second part 102 of the hollow frame structure. The mask 14 includes a blocking pattern 141 and an opening pattern 142 so that during the evaporation process, a source material (not illustrated) is disposed under the frame 10 and corresponding to the position of the central opening region 10A. The evaporating material is blocked by the blocking pattern 141, but penetrated through the opening pattern 142 so that a patterned material layer, e.g. the light-emitting layer of the OLED display panel, corresponding to the opening pattern 142 is formed on a substrate (not illustrated) to be evaporated. The mask 14 and the support structure 12 in accordance with the present embodiment may be made of the same materials of substantially the same thicknesses, so that the support structure 12 can possess light weight, but is not limited thereto.

As described in the passages above, since the support structure 12 is connected to the first connecting positions P1 of the frame 10 in a movable manner, the connecting positions between the support structure 12 and the frame 10 may be fulfill different designs of the OLED display panel, the pattern changes of the light-emitting layer or the pattern of the mask 14. Under such circumstances, the support structure 12 may be removed from the frame 10 accordingly, and the connecting positions between the support structure 12 and the frame 10 may be rearranged. As illustrated in FIG. 7, when adjustments of the connecting positions between the support structure 12 and the frame 10 are required, the mask 14 is removed from the frame 10 and the support structure 12 in advance. Then, an appropriate method is selected to detach the support structure 12 from the frame 10 based on different connecting methods used to connecting the support structure 12 and the frame 10. Subsequently, the positions and arrangements of the support structure 12 may be adjusted, the support structure 12 may be replaced, or the number of the support structure 12 may be increased or decreased. The support structure 12 is then connected to the second connecting position P2 of the frame 10 again, for instance, in the movable manner as previously presented. By virtue of connecting the support structure 12 to the frame 10 in a movable manner, the applicability of the shadow mask 20 is increased, and the replacement cost of the shadow mask 20 is therefore reduced.

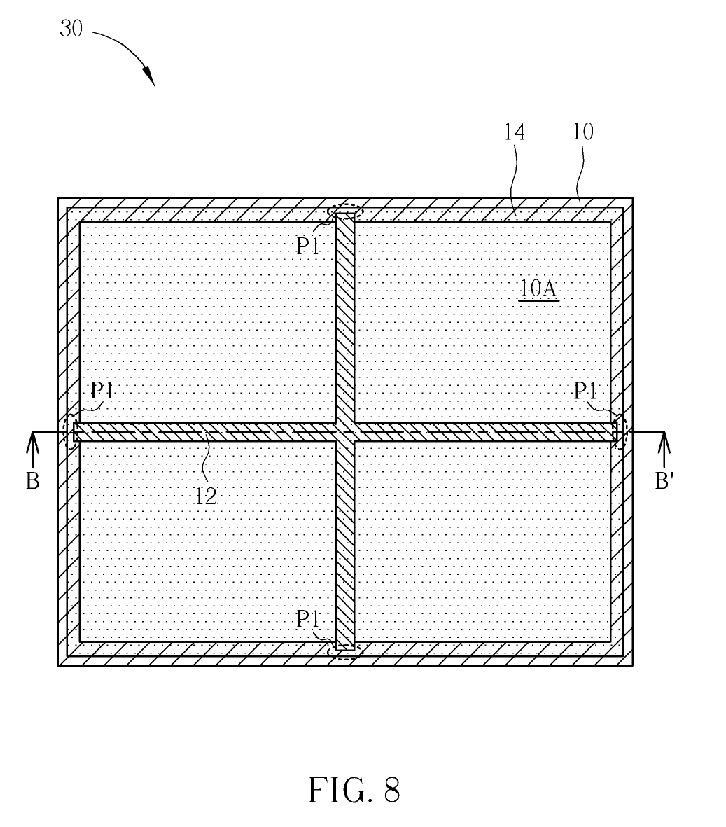

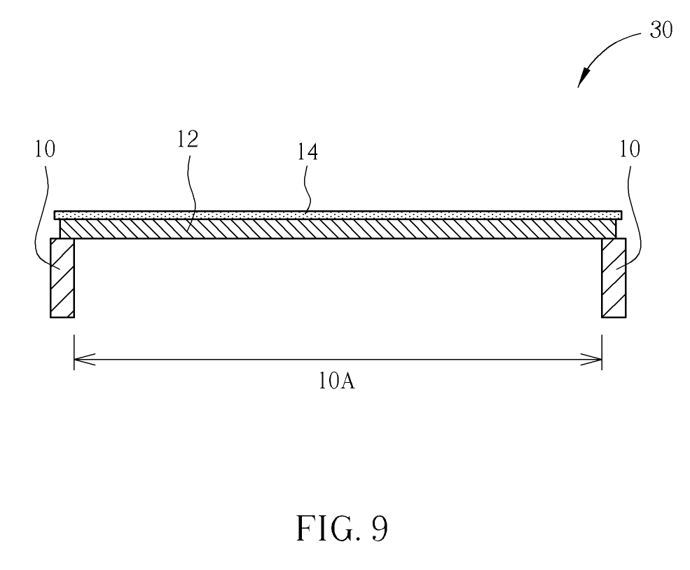

The shape of the frame of the shadow mask and the positions of the support structure in accordance with the present invention are not limited to the embodiments described above, and the present invention includes other embodiments. Referring to FIG. 8 and FIG. 9, FIG. 8 and FIG. 9 are schematic diagrams illustrating a shadow mask in accordance with another embodiment of the present invention. FIG. 8 is a schematic top view diagram of the shadow mask, and FIG. 9 is a schematic cross-sectional diagram of the shadow mask along a line B-B′ of FIG. 8. Since the materials and connecting methods between the support structure and the frame of the shadow mask are already presented in the previous embodiments, only the differences between the two embodiments are illustrated, and repeated descriptions are not redundantly given. Also, to simplify the description and for the convenience of comparison between each of the embodiments of the present invention, identical elements are denoted by identical numerals. As illustrated in FIG. 8 and FIG. 9, a frame 10 of a shadow mask 30 in accordance with the present embodiment includes a hollow frame structure. The frame 10 defines a central opening region 10A, but the frame 10 does not include parts of different thickness. Instead, the frame 10 is a structure of a substantially uniform thickness. A support structure 12 is movably connected to a first connecting position P1 on a top surface of the frame 10, and the support structure 12 may be detached from the top surface of the frame 10 through reworks or other methods. The detached support structure 12 may be reconnected to other positions on the top surface of the frame 10. In addition, a mask 14 is disposed on the support structure 12 and the mask 14 is supported by the support structure 12. During the evaporation process, a source material (not illustrated) is disposed under the shadow mask 30, and a substrate (not illustrated) to be evaporated is disposed over the shadow mask 30. It is to be noted that, in order to achieve light weight objective, the thickness of the support structure 12 may be substantially the same as the thickness of the mask 14, but not limited thereto.

The shadow mask fabricated using the method described in the present invention may be used for the manufacturing of OLED display panel or other flat display panels. The flat display panels may be applied in flat display devices, digital cameras, laptop computers, portable media players, mobile phones, video camera devices, portable information terminal devices, projection devices or other electronic devices.

In summary, the shadow mask in accordance with the present invention has a support structure movably disposed so that the connecting positions between the support structure and the frame may be adjusted accordingly, which greatly increases the applicability and flexibility of the shadow mask, and reduces the replacement cost of the shadow mask. In addition, the support structure may be made of light weight materials to effectively reduce the overall weight of the shadow mask, avoiding the issue of bending and improving the accuracy of the patterns formed by the evaporation process.

Those skilled in the art will readily observe that numerous modifications and alterations of the device and method may be made while retaining the teachings of the invention.

What is claimed is:

1. A shadow mask, comprising:
a frame, wherein the frame substantially defines a central opening region;
at least one support structure, substantially disposed in the central opening region, wherein the support structure is movably connected to the frame; and
at least one mask, substantially disposed in the central opening region, the mask being supported by the support structure.

2. The shadow mask of claim 1, wherein the support structure is connected to the frame by laser welding.

3. The shadow mask of claim 1, wherein the support structure and the mask are made of a same material.

4. The shadow mask of claim 1, wherein the support structure and the frame are made of a same material.

5. The shadow mask of claim 1, wherein the mask and the frame are made of a same material.

6. The shadow mask of claim 1, wherein the frame comprises a hollow frame structure.

7. The shadow mask of claim 6, wherein the hollow frame structure comprises a first part and a second part, the first part is disposed near the central opening region, the second part is disposed away from the central opening region, and a thickness of the first part is thinner than a thickness of the second part so that the hollow frame structure has an L-shaped cross-section, the mask is disposed on the support structure and the first part of the hollow frame structure, and the mask is lodged in the second part of the hollow frame structure.

8. The shadow mask of claim 1, wherein the frame has a substantially uniform thickness, and the support structure is disposed on a top surface of the frame.

9. The shadow mask of claim 8, wherein a thickness of the support structure and a thickness of the mask are substantially the same.

10. A method of fabricating a shadow mask, comprising:
providing a frame, wherein the frame substantially defines a central opening region;
connecting at least one support structure to at least a first connecting position of the frame in a movable manner, and disposing the support structure in the central opening region; and
disposing at least one mask substantially in the central opening region, wherein the mask is supported by the support structure.

11. The method of claim 10, wherein the support structure is connected to the frame by laser welding.

12. The method of claim 10, wherein the support structure and the mask are made of a same material.

13. The method of claim 10, wherein the support structure and the frame are made of a same material.

14. The method of claim 10, wherein the mask and the frame are made of a same material.

15. The method of claim 10, further comprising:
disconnecting the support structure from the first connecting position of the frame; and
connecting the support structure to at least a second connecting position of the frame in a movable manner.

16. The method of claim 10, wherein the frame comprises a hollow frame structure.

17. The method of claim 16, wherein the hollow frame structure comprises a first part and a second part, the first part is disposed near the central opening region, the second part is disposed away from the central opening region, and a thickness of the first part is thinner than a thickness of the second part so that the hollow frame structure has an L-shaped cross-section, the mask is disposed on the support structure and the first part of the hollow frame structure, and the mask is lodged in the second part of the hollow frame structure.

18. The method of claim 10, wherein the frame has a substantially uniform thickness, and the support structure is disposed on a top surface of the frame.

19. The method of claim 18, wherein a thickness of the support structure and a thickness of the mask are substantially the same.
